(19) United States
(12) Patent Application Publication
(10) Pub. No.: US 2025/0107291 A1
(43) Pub. Date: Mar. 27, 2025

(54) DISPLAY MODULE AND METHOD FOR FORMING THE SAME

(71) Applicant: AUO Corporation, HSIN-CHU (TW)

(72) Inventors: Han-Chung LAI, HSIN-CHU (TW); Wen-Jen LI, HSIN-CHU (TW); Rong-Sheng TSAI, HSIN-CHU (TW)

(21) Appl. No.: 18/395,787

(22) Filed: Dec. 26, 2023

(30) Foreign Application Priority Data
Sep. 23, 2023 (TW) 112136478

(51) Int. Cl. H01L 33/54; H01L 25/16; H01L 33/62

(52) U.S. Cl. CPC H10H 20/853; H01L 25/167; H10H 20/857; H10H 20/0362; H10H 20/0364

(57) ABSTRACT

A display module includes a light-emitting element, a molding layer, a metal contact, an insulating layer, and an array substrate. The light-emitting element has a first surface and a second surface opposite to each other. The light-emitting element has a lead disposed on the first surface. The molding layer laterally surrounds the light-emitting element and has a first surface and a second surface opposite to each other. The first surface of the molding layer is adjacent to the first surface of the light-emitting element. The first surface of the molding layer is a coarse surface. The metal contact covers the lead of the light-emitting element. The insulating layer covers the metal contact and the molding layer. The array substrate is disposed on the insulating layer and having a pad configured to be electrically connected to the metal contact.

### CROSS-REFERENCE TO RELATED APPLICATION

This application claims priority to Taiwan Application Serial Number 112136478, filed Sep. 23, 2023, which is herein incorporated by reference.

### BACKGROUND

### Technical Field

The present disclosure relates to a display module and a method for forming the same.

### Description of Related Art

In the manufacturing processes of common display modules, light-emitting diodes (LEDs) undergo a number of mass transfers before encapsulation. These light-emitting diodes are adhered onto a wafer or a carrier through colloid and are peeled off from the wafer or the carrier through a laser lift-off (LLO) process during the mass transfers. Therefore, before the light-emitting diodes are bonded to a circuit board, a process for removing the colloid is performed (e.g., through ion bombardment) to remove adhesive residues on the light-emitting diodes. Otherwise, the electrical connections of the light-emitting diodes formed in subsequent processes may be adversely affected.

However, during the removal processes, the adhesive layer used for positioning the light-emitting diodes onto a later carrier or substrate may be destroyed as well, causing displacement of the light-emitting diodes. Consequently, the electrical connections may fail due to misalignment. Besides, as the critical dimensions of the light-emitting diodes continue to shrink, the displacement caused by the removal process has become an issue.

Accordingly, how to provide a display module and a method for forming the display module to solve the aforementioned problems becomes an important issue to be solved by those in the industry.

### SUMMARY

An aspect of the disclosure is to provide a display module and a method for forming the display module that may efficiently solve the aforementioned problems.

According to an embodiment of the disclosure, a display module includes a light-emitting element, a molding layer, a metal contact, an insulating layer, and an array substrate. The light-emitting element has a first surface and a second surface opposite to each other. The light-emitting element further includes a lead disposed on the first surface. The molding layer laterally surrounds the light-emitting element and has a first surface and a second surface opposite to each other. The first surface of the molding layer is adjacent to the first surface of the light-emitting element. The first surface of the molding layer is a coarse surface. The metal contact covers the lead of the light-emitting element. The insulating layer covers the metal contact and the molding layer. The array substrate is disposed on the insulating layer and having a pad configured to be electrically connected to the metal contact.

In an embodiment of the disclosure, a roughness of the first surface of the molding layer is greater than a roughness of the second surface of the molding layer.

In an embodiment of the disclosure, a roughness of the first surface of the molding layer is greater than a roughness of a surface of the metal contact.

In an embodiment of the disclosure, a roughness of the first surface of the molding layer is greater than a roughness of the second surface of the light-emitting element.

In an embodiment of the disclosure, the molding layer covers the first surface of the light-emitting element. The lead of the light-emitting element passes through the molding layer and contacts the metal contact.

In an embodiment of the disclosure, the lead of the light-emitting element protrudes from the first surface of the molding layer.

In an embodiment of the disclosure, the metal contact extends from an upper surface of the lead, through a side surface of the lead, to the first surface of the molding layer.

In an embodiment of the disclosure, the display module further includes a touch sensing electrode disposed on the second surface of the molding layer. The touch sensing electrode is configured to receive a first driving signal. The metal contact is configured to receive a second driving signal. The second driving signal is different from the first driving signal.

According to another embodiment of the disclosure, a method for forming a display module includes providing a carrier with a light-emitting element. The light-emitting element is disposed on the carrier through an adhesive layer. The light-emitting element has a plurality of leads disposed on a surface of the light-emitting element that is opposite to the carrier. The plurality of leads is covered by an adhesive residue. The adhesive residue is separated from the surface of the light-emitting element. The method further includes forming a molding layer to cover the carrier and laterally surrounding the light-emitting element. The method further includes performing an etching process to remove the adhesive residue to expose the plurality of leads and to form a first surface of the molding layer into a coarse surface. The first surface of the molding layer is opposite to the carrier. The method further includes forming a plurality of metal contacts covering the plurality of leads. The plurality of metal contacts is separated from each other. The method further includes disposing an array substrate electrically connected to the plurality of metal contacts.

In an embodiment of the disclosure, the method further includes peeling off the carrier and performing another etching process to remove the adhesive layer to expose a light-emitting surface of the light-emitting element and to form a second surface of the molding layer opposite to the first surface into a coarse surface. A roughness of the second surface is smaller than a roughness of the first surface.

In an embodiment of the disclosure, a roughness of the light-emitting surface of the light-emitting element is smaller than a roughness of the first surface of the molding layer.

In an embodiment of the disclosure, after removing the adhesive layer, the light-emitting element protrudes from the second surface of the molding layer.

In an embodiment of the disclosure, a roughness of the first surface of the molding layer is greater than a roughness of a plurality of surfaces of the plurality of metal contacts.

In an embodiment of the disclosure, after removing the adhesive residue, the plurality of leads of the light-emitting element protrudes from the first surface of the molding layer.

In an embodiment of the disclosure, the adhesive layer is protected by the molding layer during the etching process.

Accordingly, in the display module and the method for forming the display module of some embodiments of the present disclosure, by disposing a molding layer laterally surrounding the light-emitting elements and covering part of the surfaces of the light-emitting elements, the light-emitting elements can be firmly positioned. At the same time, the molding layer can act as a protective layer during the manufacturing processes to prevent the adhesive layers used for positioning the light-emitting elements and/or the light-emitting surfaces of the light-emitting elements from being affected by the ion bombardment processes. Thus, the success rate of bonding the light-emitting elements may be ensured. To be more specific, after the first mass transfer, a molding layer is formed to laterally surround the light-emitting elements and cover part of the surfaces of the light-emitting elements to protect the adhesive layer that positions the light-emitting elements and/or the light-emitting surfaces of the light-emitting elements when the adhesive residues resulted from the first mass transfer is removed. The molding layer is affected by the ion bombardment processes and thus a surface of the molding layer that is adjacent to where the light-emitting elements are adhered is formed into a coarse surface. Compared with common display modules and methods for forming display modules, the positioning of the light-emitting elements can be strengthened, thereby improving the success rate of bonding and electrically connecting the light-emitting elements.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a partial cross-sectional view of a display module according to an embodiment of the present disclosure;

FIG. 2 is an partial enlarged view of a square 2 of a display module in FIG. 1 according to an embodiment of the present disclosure;

FIG. 3 is an partial enlarged view of a square 3 of a display module in FIG. 1 according to an embodiment of the present disclosure;

FIG. 4 and FIG. 5 are schematic diagrams of a display module according to an embodiment of the present disclosure;

FIG. 6 is a flow chart of a method for forming a display module according to an embodiment of the present disclosure;

FIG. 7 to FIG. 12 are partial cross-sectional views of intermediate stages of a method for forming a display module according to an embodiment of the present disclosure;

FIG. 13 is a partial cross-sectional view of a display module according to an embodiment of the present disclosure;

FIG. 14 is a schematic diagram of a display module according to an embodiment of the present disclosure;

FIG. 15 is a partial cross-sectional view of a display module according to an embodiment of the present disclosure;

FIG. 16 is a partial cross-sectional view of a display module according to an embodiment of the present disclosure; and

FIG. 17 is a partial cross-sectional view of a display module according to an embodiment of the present disclosure.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

In the mass transfers of light-emitting diodes (LEDs), monochromatic light-emitting diodes grown on a wafer (chip on wafer, COW) may be placed onto a first carrier (chip on carrier, COC) according to a required pitch by a first mass transfer. These monochromatic light-emitting diodes are peeled off from the wafer through a laser lift-off (LLO) process and are adhered to the first carrier through a special colloid. For example, leads of the light-emitting diodes are adhered to the first carrier through a silicone-containing adhesive material. Then, according to the specification requirements of the pixel units of the display device, the light-emitting diodes with red light, green light, and blue light are sequentially transferred from the first carrier to a second carrier. During the mass transfer, laser is used to reduce the viscosity of the colloid and to separate the colloid from the surface of the first carrier. After removing the colloid with laser, some of the colloid (hereinafter “adhesive residues”) may remain on the light-emitting diodes such as around the leads. Therefore, after the light-emitting diodes are transferred to the second carrier, a specific adhesive residue removal process may be performed, such as through ion bombardment, to prevent the adhesive residues from affecting the electrical connections in subsequent processes.

However, if the light-emitting diodes are adhered to the second carrier through an adhesive layer with a similar composition as the adhesive residues, the adhesive layer may be damaged when the adhesive residues are removed through ion bombardment. Therefore, the damaged adhesive layer may result in the shifting of the light-emitting diodes and cause mounting and bonding failures when the light-emitting diodes are transferred from the second carrier to an array substrate.

Therefore, some embodiments of the present disclosure aim to provide a display module and a method for forming the display module that enhance the positioning of light-emitting diodes and improve the success rate of mass transfers.

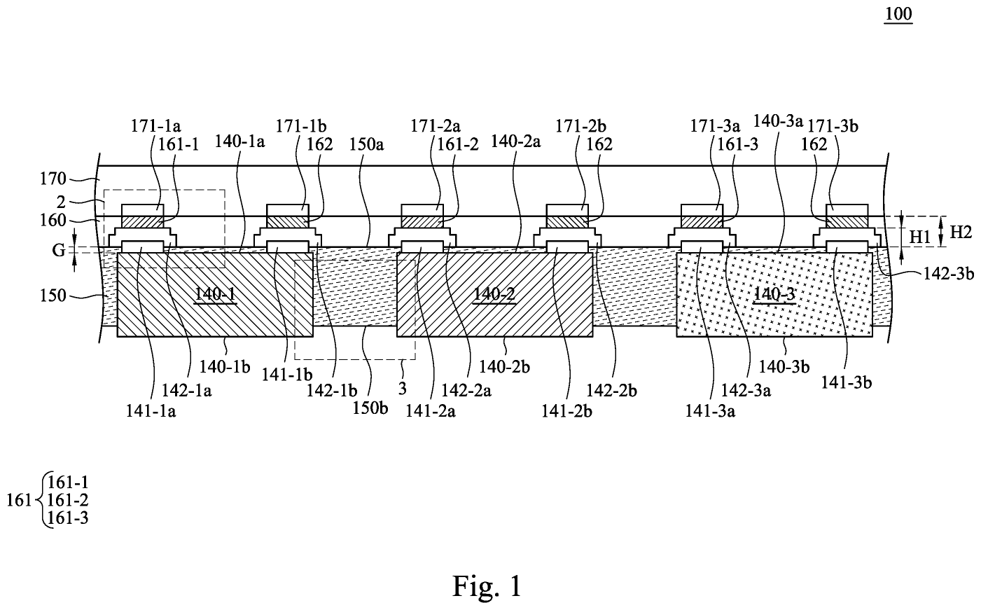

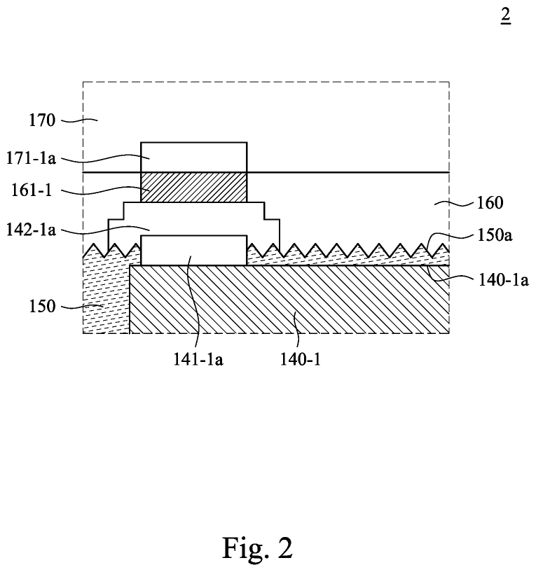

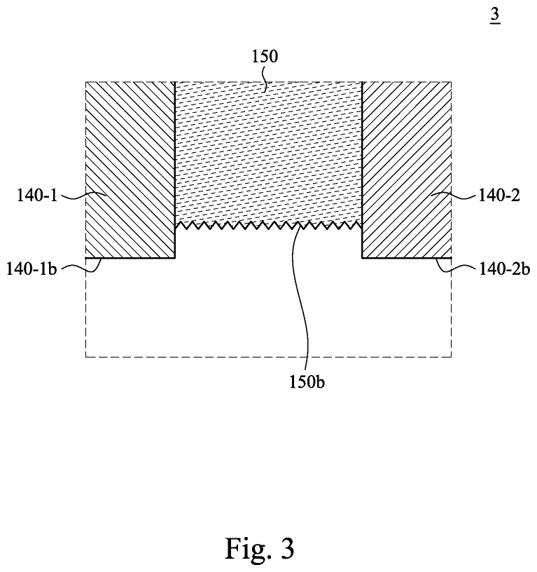

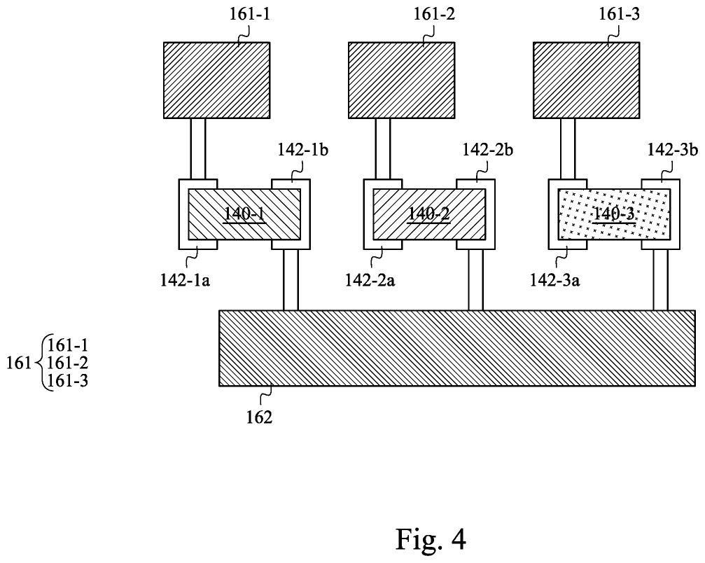

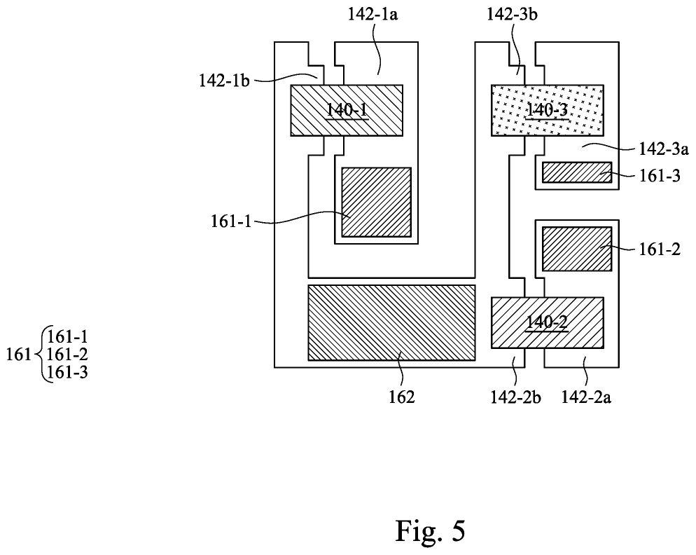

Reference is made to FIG. 1 to FIG. 5. FIG. 1 is a partial cross-sectional view of a display module 100 according to some embodiments of the present disclosure. FIG. 2 is a partial enlarged view of a square 2 of the display module 100 in FIG. 1. FIG. 3 is a partial enlarged view of a square 3 of the display module 100 in FIG. 1. FIG. 4 and FIG. 5 are schematic diagrams of the display module 100 according to some embodiments of the present disclosure. It should be noted that some components such as the molding layer 150 are omitted from the schematic diagrams such as FIG. 4 and FIG. 5 for clarity.

In some embodiments of the present disclosure, a display module includes a plurality of light-emitting elements, a molding layer, an insulating layer, and an array substrate. For example, as shown in FIG. 1, the display module 100 includes a light-emitting element 140-1, a light-emitting element 140-2, a light-emitting element 140-3, a molding layer 150, an insulating layer 160, and an array substrate 170. These light-emitting elements may correspond to different colors, so the area shown in FIG. 1 can be regarded as a pixel unit.

The light-emitting element includes multiple leads. In some embodiments, each light-emitting element includes a first lead and a second lead. The first lead is configured to provide a first voltage potential. The second lead is configured to provide a second voltage potential. The second voltage potential is different from the first voltage potential. For example, the first voltage potential is a high-level potential. The second voltage potential is a low-level potential or a ground potential. As shown in FIG. 1, the light-emitting element 140-1 includes a first lead 141-1a and a second lead 141-1b. The light-emitting element 140-2 includes a first lead 141-2a and a second lead 141-2b. The light-emitting element 140-3 includes a first lead 141-3a and a second lead 141-3b.

In some embodiments, the light-emitting element is a light-emitting diode and includes a first semiconductor layer, a second semiconductor layer, and a light-emitting layer disposed between the first semiconductor layer and the second semiconductor layer. In such embodiments, the first lead that provides the first voltage potential is connected to the first semiconductor layer, such as a p-type semiconductor layer. The second lead that provides the second voltage potential is connected to the second semiconductor layer, such as an n-type semiconductor layer. However, this disclosure is not limited thereto.

In addition, each light-emitting element has a first surface and a second surface opposite to each other. As shown in FIG. 1, the light-emitting element 140-1 includes a first surface 140-1a and a second surface 140-1b. The light-emitting element 140-2 includes a first surface 140-2a and a second surface 140-2b. The light-emitting element 140-3 includes a first surface 140-3a and a second surface 140-3b. In some embodiments, the second surfaces of these light-emitting elements are light-emitting surfaces.

In some embodiments, the light-emitting element further includes a plurality of metal contacts. The number of the metal contacts corresponds to the number of the leads. As shown in FIG. 1, the light-emitting element 140-1 includes a metal contact 142-1a and a metal contact 142-1b. The light-emitting element 140-2 includes a metal contact 142-2a and a metal contact 142-2b. The light-emitting element 140-3 includes a metal contact 142-3a and a metal contact 142-3b.

It should be understood that although the actual sizes of the light-emitting element 140-1, the light-emitting element 140-2, and the light-emitting element 140-3 may differ due to limitations of the semiconductor materials, the structures of the light-emitting element 140-1, the light-emitting element 140-2, and the light-emitting element 140-3 are similar. Also, their connections and configurations with other components are similar. Therefore, in the following paragraphs, the structural features of the light-emitting elements will be described using the light-emitting element 140-1 as a representative. The structural features of the light-emitting element 140-2 and the light-emitting element 140-3 can be deduced by analogy and will not be described in detail.

In some embodiments, as shown in FIG. 1, two leads of the light-emitting element are disposed on the first surface. For example, as shown in FIG. 1, the first lead 141-1a and the second lead 141-1b are disposed on the first surface 140-1a.

In some embodiments, the metal contacts of the light-emitting elements cover the leads. For example, as shown in FIG. 1, the metal contact 142-1a of the light-emitting element 140-1 covers the first lead 141-1a.

It should be noted that in some embodiments, there is a gap between the metal contact and the first surface of the light-emitting element and the two do not contact each other. For example, as shown in FIG. 1, there is a gap G between the metal contact 142-1a and the first surface 140-1a of the light-emitting element 140-1.

The array substrate 170 includes a plurality of pads. In some embodiments, as shown in FIG. 1, the array substrate 170 includes a first pad 171-1a, a second pad 171-1b, a first pad 171-2a, a second pad 171-2b, a first pad 171-3a, and a second pad 171-3b.

In some embodiments, the light-emitting elements are electrically connected to the pads of the array substrate 170 through the metal contacts. For example, as shown in FIG. 1, the metal contact 142-1a and the metal contact 142-1b of the light-emitting element 140-1 are electrically connected to the first pad 171-1a and the second pad 171-1b of the array substrate 170, respectively.

As shown in FIG. 1, the molding layer 150 has a first surface 150a and a second surface 150b opposite to each other. The first surface 150a of the molding layer 150 is adjacent to the first surfaces of the light-emitting elements. For example, the first surface 150a is adjacent to the first surface 140-1a of the light-emitting element 140-1. The second surface 150b of the molding layer 150 is adjacent to the second surfaces (i.e., the light-emitting surfaces) of the light-emitting elements. For example, the second surface 150b is adjacent to the second surface 140-1b of the light-emitting element 140-1.

The molding layer 150 of the display module 100 laterally surrounds the light-emitting elements. To be more specific, the molding layer 150 laterally surrounds part of sidewalls of the light-emitting elements. As shown in FIG. 1, the molding layer 150 laterally surrounds part of a sidewall of the leads of the light-emitting elements. Therefore, the leads of the light-emitting elements protrude from the first surface 150a of the molding layer 150. For example, as shown in FIG. 1 and FIG. 2, the first lead 141-1a of the light-emitting element 140-1 protrudes from the first surface 150a. In other words, the leads of the light-emitting elements extend through the molding layer 150 and contact the metal contacts. For example, the first lead 141-1a of the light-emitting element 140-1 extends through the molding layer 150 and contacts the metal contact 142-1a. In addition, the molding layer 150 covers the first surfaces of the light-emitting elements. For example, the molding layer 150 covers the first surface 140-1a of the light-emitting element 140-1, as shown in FIG. 1 and FIG. 2.

At the same time, as shown in FIG. 1 and FIG. 3, the second surfaces of the light-emitting elements protrude from the second surface 150b of the molding layer 150. For example, the second surface 140-1b of the light-emitting element 140-1 protrudes from the second surface 150b.

In some embodiments, the molding layer 150 may include inorganic materials. For example, silicon oxide, silicon nitride, silicon oxynitride, other suitable materials, or a stacked structure including at least two of the aforementioned materials. In some embodiments, the molding layer 150 may include organic materials. For example, polyesters such as PET, polyolefins, polypropylene, polycarbonate (PC), polyalkylene oxides, polystyrenes (PS), polyethers, and polyketides, polyols, polyaldehydes, other suitable materials, or combinations of the aforementioned materials.

Reference is made to FIG. 2 and FIG. 3. It should be noted that the first surface 150a of the molding layer 150 is a coarse surface, as shown in FIG. 2. In some embodiments, the second surface 150b of the molding layer 150 is also a coarse surface, as shown in FIG. 3. Furthermore, a roughness of the first surface 150a of the molding layer 150 is greater than a roughness of the second surface 150b of the molding layer 150, as shown in FIG. 2 and FIG. 3. It should be noted that the term “roughness” in this disclosure refers to a surface roughness. The greater the surface roughness is, the greater the difference between the highest point and the lowest point of the surface is.

In addition, the roughness of the first surface 150a of the molding layer 150 is greater than a roughness of the surface of the metal contact, such as the metal contact 142-1a. At the same time, the roughness of the first surface 150a of the molding layer 150 is greater than a roughness of the second surfaces of the light-emitting elements, such as the second surface 140-1b of the light-emitting element 140-1.

Reference is made back to FIG. 1. As shown in FIG. 1, the insulating layer 160 of the display module 100 covers the metal contacts of the light-emitting elements, such as the metal contact 142-1a of the light-emitting elements 140-1. At the same time, the insulating layer 160 covers the molding layer 150. In some embodiments, the insulating layer 160 conformally covers the first surface 150a of the molding layer 150. Therefore, the surface undulation of the insulating layer 160 is similar to the surface undulation of the coarse surface of the first surface 150a. In other words, the roughness of the first surface 150a is close to a roughness of the insulating layer 160. In some embodiments, the insulating layer 160 is configured to act as a planarization layer as shown in FIG. 1. As a result, the roughness of the first surface 150a is greater than the roughness of the insulating layer 160.

It should be noted that in some embodiments, as shown in FIG. 1, the insulating layer 160 does not contact the first surfaces of the light-emitting elements, such as the first surface 140-1a of the light-emitting element 140-1. Furthermore, there is a gap G between the bottom surface of the insulating layer 160 and the first surfaces of the light-emitting elements.

As shown in FIG. 1, a maximum height H1 of the metal contacts of the light-emitting elements relative to the first surface 150a of the molding layer 150 is about 0.3 μm. A height H2 of the insulating layer 160 is in a range from about 1.2 μm to 3 μm.

In some embodiments, the insulating layer 160 may include bonding layers, such as a bonding layer 161 and a bonding layer 162 shown in FIG. 1. The bonding layers are filled in the insulating layer 160 and connect the metal contacts of the light-emitting elements with the pads of the array substrate 170. For example, as shown in FIG. 1, the bonding layer 161 is filled in the insulating layer 160, and a portion of the bonding layer 161 (i.e., the bonding layer 161-1) connects the metal contact 142-1a of the light-emitting element 140-1 with the first pad 171-1a of the array substrate 170.

It should be noted that the bonding layer can extend in the insulating layer 160 and is not limited to the structure shown in FIG. 1. The pads of the array substrate 170 can be disposed in accordance with the position of the bonding layer and is not limited to the structure in FIG. 1. For example, as shown in FIG. 4, the metal contact 142-1a, the metal contact 142-2a, and the metal contact 142-3a can extend through wiring to be connected to the bonding layer 161-1, the bonding layer 161-2, and the bonding layer 161-3, respectively. The bonding layer 161-1, the bonding layer 161-2, and the bonding layer 161-3 are referred to as the bonding layer 161 collectively. The metal contact 142-1b, the metal contact 142-2b, and the metal contact 142-3b can extend through wiring to be connected to the bonding layer 162. In some embodiments, the bonding layer 161 is configured to connect the first voltage potential. The bonding layer 162 is configured to connect the second voltage potential. In some embodiments, the second voltage potential is a ground potential. As such, the metal contact 142-1b, the metal contact 142-2b, and the metal contact 142-3b can extend to directly connect to one single bonding layer 162. In some embodiments, the bonding layers of adjacent pixel units connected to the ground potential can be connected in series with one another.

By disposing the bonding layer 161 and the bonding layer 162, the area for establishing electrical connections between the metal contacts of the light-emitting elements and the pads of the array substrate 170 can be increased, thereby allowing the application of different connection methods. For example, the bonding layer 161 and the bonding layer 162 can be disposed between the metal contacts and the pads using silver paste for traditional encapsulation or eutectic welding. Also, anisotropic conductive film (ACF) can be coated and thermally pressed to form the bonding layer 161 and the bonding layer 162 for bonding between the metal contacts and the bonding pads. Therefore, the materials of the bonding layer 161 and the bonding layer 162 may include anisotropic conductive film, silver, tin, gold, aluminum, or the like. In this way, the traditional drilling process can be eliminated and the reliability of wire bonding can be increased.

In some embodiments, as shown in FIG. 5, the light-emitting elements are arranged in an L shape. The bonding layer 161 and the bonding layer 162 can be arranged in accordance with the positions of the light-emitting elements to serially connect signals of the same potential.

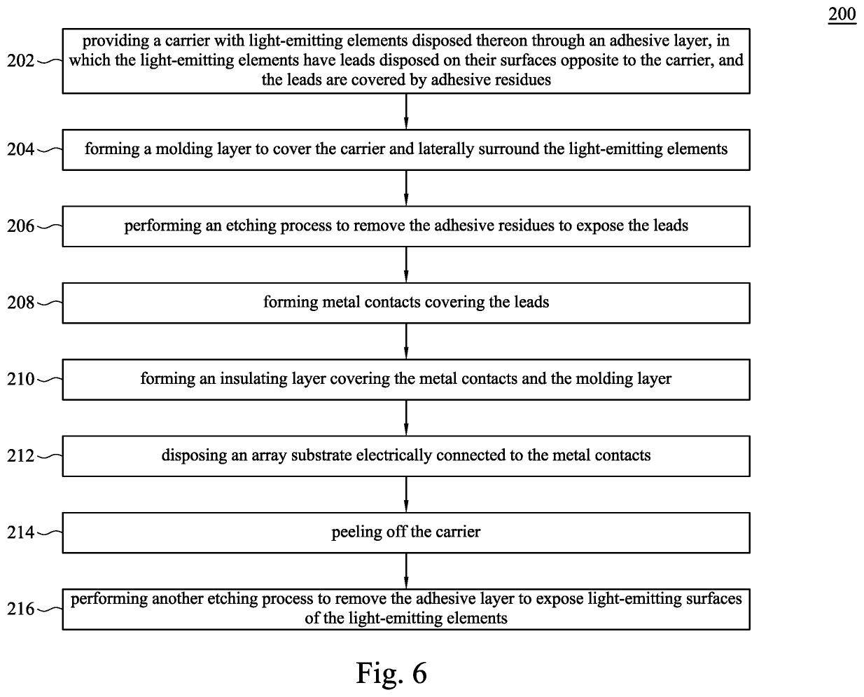

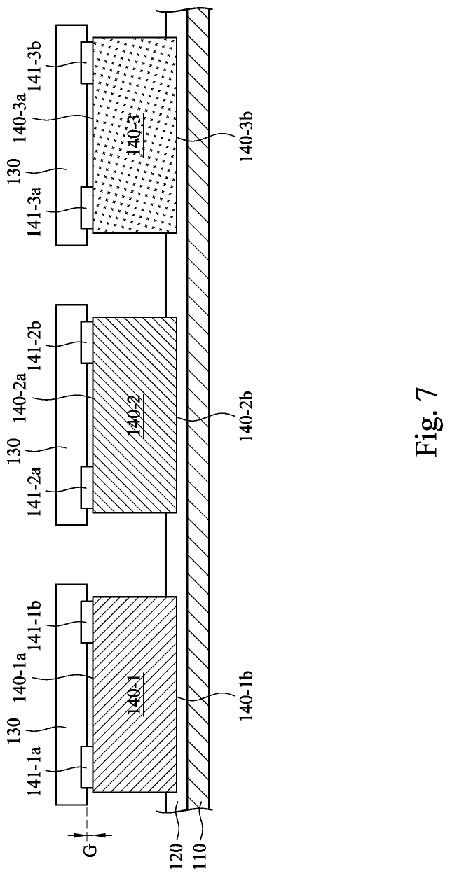

Reference is made to FIG. 6 to FIG. 12. FIG. 6 is a flowchart of a method 200 for forming the display module 100 according to some embodiments of the present disclosure. FIG. 7 to FIG. 12 are partial cross-sectional views of intermediate stages of the method 200 according to some embodiments of the present disclosure.

As shown in FIG. 6, the method 200 includes a step 202 to a step 216. In the following paragraphs, each step will be explained with its corresponding partial cross-sectional views.

Reference is made to FIG. 7. First, the method 200 includes a step 202. The step 202 includes providing a carrier with a plurality of light-emitting elements disposed thereon. As shown in FIG. 7, a light-emitting element 140-1, a light-emitting element 140-2, and a light-emitting element 140-3 are disposed on a carrier 110 through an adhesive layer 120. Each light-emitting element has a plurality of leads and has a first surface and a second surface opposite to each other. For example, the light-emitting element 140-1 has a first lead 141-1a, a second lead 141-1b, a first surface 140-1a, and a second surface 140-1b. The first surface of the light-emitting element is away from a surface of the carrier 110. The second surface of the light-emitting element is adjacent to the surface of the carrier 110 and in contact with the adhesive layer 120, as shown in FIG. 7. The leads are disposed on the first surface of the light-emitting element and covered by an adhesive residue 130. In some embodiments, the adhesive residue 130 results from an adhesive layer of another carrier where the light-emitting element was placed before the latest mass transfer. It should be noted that, as shown in FIG. 7, the adhesive residue 130 and the first surface of the light-emitting element are separated from each other. For example, there is a gap G between the adhesive residue 130 and the first surface 140-1a of the light-emitting element 140-1.

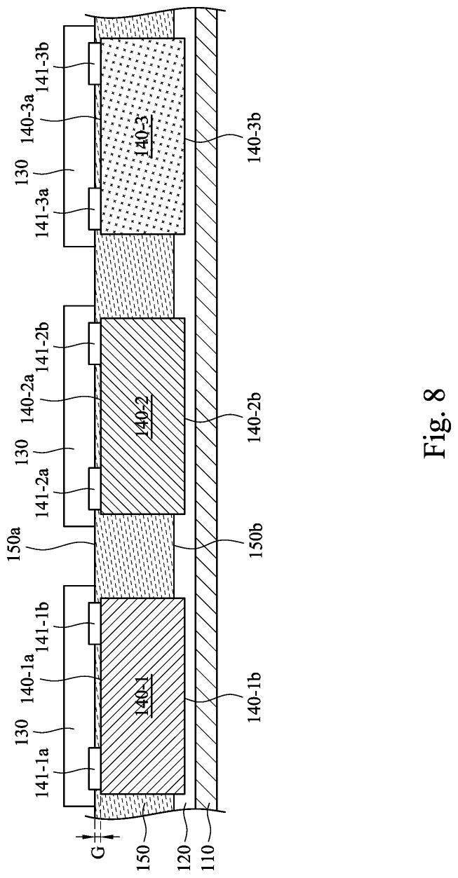

Reference is made to FIG. 8. Next, the method 200 includes a step 204. The step 204 includes forming a molding layer to cover the carrier and laterally surround the light-emitting elements. As shown in FIG. 8, a molding layer 150 covers the carrier 110 and the adhesive layer 120, and laterally surrounds part of the sidewalls of the light-emitting element 140-1, the light-emitting element 140-2, and the light-emitting element 140-3. As shown in FIG. 8, the leads of the light-emitting element penetrate through the molding layer 150 and protrude from a first surface 150a of the molding layer 150. To be more specific, the molding layer 150 and the adhesive layer 120 jointly cover the sidewalls of the light-emitting element 140-1, the light-emitting element 140-2, and the light-emitting element 140-3. At the same time, the molding layer 150 covers the first surfaces of the light-emitting elements and fills the gap G between the adhesive residue 130 and the first surfaces.

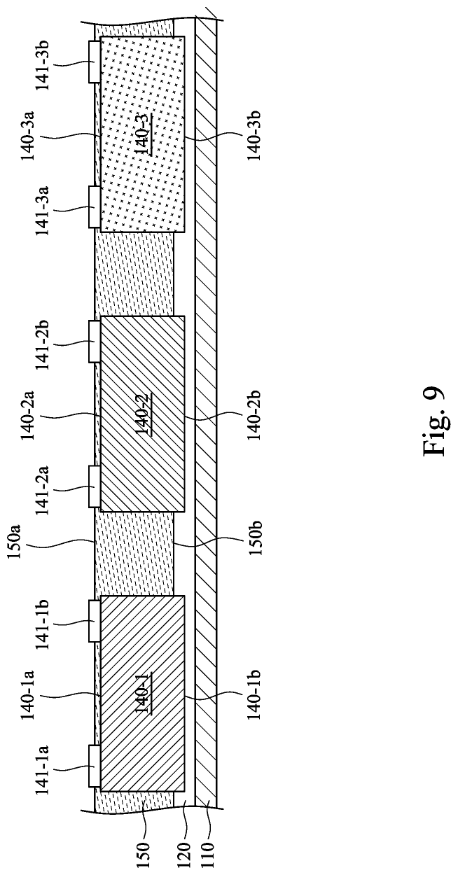

Reference is made to FIG. 9. Next, the method 200 includes a step 206. The step 206 includes performing an etching process to remove the adhesive residues (such as the adhesive residues 130) covering the leads to expose the leads. As shown in FIG. 9, after the step 206 is completed, the leads of the light-emitting elements are exposed through the molding layer 150. In some embodiments, the etching process is an ion etching process. For example, an ion bombardment etching process is performed using etching gases such as oxygen, carbon tetrafluoromethane (CF₄), sulfur hexafluoride (SF₆), or argon (Ar). During the ion etching process, the molding layer 150 acts as a protective layer to prevent the adhesive layer 120 and the carrier 110 from being bombarded by ions. At the same time, the molding layer 150 can facilitate the positioning of the light-emitting elements and prevent the light-emitting elements from displacing during the removal of the adhesive residue 130. Since the molding layer 150 is exposed to ion bombardment, after the step 206 is completed, the first surface 150a of the molding layer 150 is formed into a coarse surface (as shown with the first surface 150a in FIG. 2).

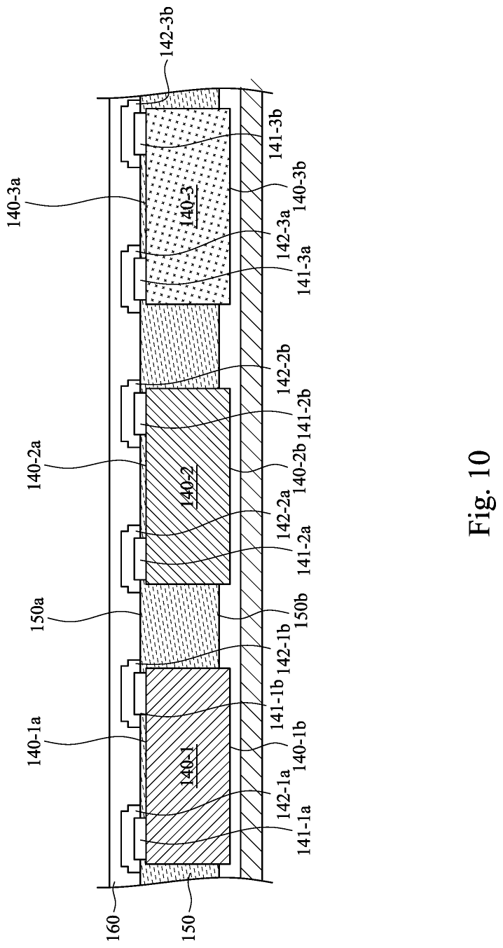

Reference is made to FIG. 10. Next, the method 200 includes a step 208. The step 208 includes forming a plurality of metal contacts to cover the leads. As shown in FIG. 10, the metal contacts cover the portions of the leads protruding from the molding layer 150. For example, the metal contact 142-1a extends from an upper surface of the first lead 141-1a through a side surface of the first lead 141-1a to the first surface 150a of the molding layer 150. In other words, the molding layer 150 and the metal contacts jointly cover the leads. In the cross-sectional view shown in FIG. 10, the metal contact 142-1a, the metal contact 142-1b, the metal contact 142-2a, the metal contact 142-2b, the metal contact 142-3a, and the metal contact 142-3b are separated from one another. It should be noted that since the metal contacts are formed after the etching process, a surface roughness of the metal contacts is smaller than the roughness of the first surface 150a of the molding layer 150.

Reference is still made to FIG. 10. Next, the method 200 includes a step 210. The step 210 includes forming an insulating layer covering the metal contacts and the molding layer. As shown in FIG. 10, the insulating layer 160 is formed and covers the metal contacts and the molding layer 150. In some embodiments, the insulating layer 160 conformally covers the first surface 150a of the molding layer 150, so that the surface undulation of the insulating layer 160 is similar to the surface undulation of the coarse surface of the molding layer 150 (i.e., the first surface 150a). As such, the roughness of the first surface 150a of the molding layer 150 is close to that of the insulating layer 160. In some embodiments, the insulating layer 160 acts as a planarization layer, as shown in FIG. 10. The roughness of the first surface 150a of the molding layer 150 is greater than that of the insulating layer 160.

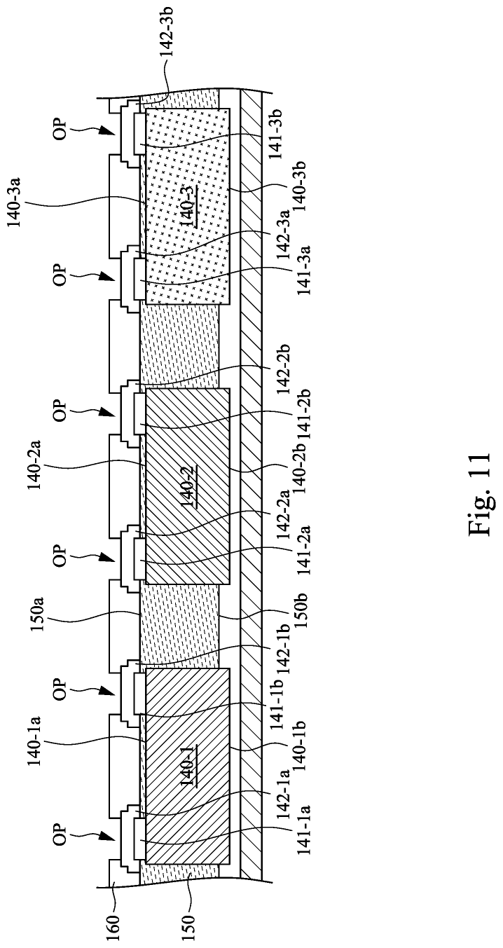

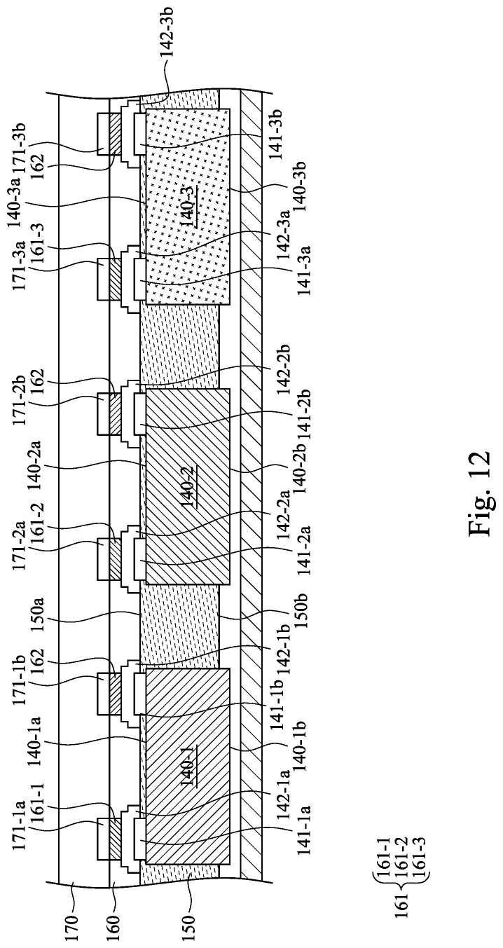

Reference is made to FIG. 11 and FIG. 12. Next, the method 200 includes a step 212. The step 212 includes disposing an array substrate 170 electrically connected to the metal contacts of the light-emitting elements, for example, through pads of the array substrate 170. It should be noted that, in some embodiments, the pads of the array substrate 170 do not directly contact the metal contacts of the light-emitting elements. For example, as described above with reference to FIG. 4, the metal contact 142-1a, the metal contact 142-2a, and the metal contact 142-3a can extend to be connected to the bonding layer 161, and then be electrically connected to a first pad of the array substrate 170 through the bonding layer 161. The metal contact 142-1b, the metal contact 142-2b, and the metal contact 142-3b can extend to be connected to the bonding layer 162, and then be electrically connected to a second pad of the array substrate 170 through the bonding layer 162.

FIG. 11 and FIG. 12 illustrate the formation of the bonding layer and the array substrate 170 according to some embodiments. As shown in FIG. 11, a plurality of openings OP is formed in the insulating layer 160 so that the metal contacts are exposed from the openings OP. Later, as shown in FIG. 12, the bonding layer 161 and the bonding layer 162 are disposed in the opening OP. Then, the bonding layer 161, the bonding layer 162, and the array substrate 170 are electrically connected.

As aforementioned, in some embodiments of the present disclosure, since the bonding layer 161 and the bonding layer 162 are provided to increase the area of electrical connection, different connection methods can be applied to bond the metal contacts and pads. For example, silver paste for traditional encapsulation or eutectic welding can be used, or anisotropic conductive film can be applied for thermal compression bonding. In this way, the traditional drilling process can be eliminated and the reliability of wire bonding can be increased.

Next, the method 200 includes a step 214 and a step 216. In the step 214, the carrier 110 is peeled off from the intermediate structure of the display module 100 in FIG. 12. Then, the step 216 follows to perform another etching process to remove the adhesive layer 120 to expose the light-emitting surfaces (i.e., the second surface) of the light-emitting elements. To be more specific, an etching process is performed so that the light-emitting elements protrude from the second surface 150b of the molding layer 150. After completing the step 216, the display module 100 in FIG. 1 is formed.

It should be noted that to prevent the etching process from causing damage to the light-emitting surfaces of the light-emitting elements and affecting the light emission, an etching process that can remove the adhesive layer 120 without damaging the light-emitting surfaces is applied. For example, an ion bombardment etching process with etching gases such as oxygen, carbon tetrafluoride, sulfur hexafluoride, or argon is performed. As a result, the roughness of the light-emitting surfaces of the light-emitting elements, such as the second surface 140-1b of the light-emitting element 140-1, is smaller than the roughness of the first surface 150a of the molding layer 150.

In addition, in the step 216, etching causes the second surface 150b of the molding layer 150 to form into a coarse surface. In order to protect the light-emitting surfaces from being affected by the etching process, the etching intensity in the step 216 is lower than that in the step 206, so a degree of etching of the second surface 150b of the molding layer 150 is lower than a degree of etching of the first surface 150a. In other words, the roughness of the second surface 150b of the molding layer 150 is smaller than the roughness of the first surface 150a.

In some embodiments, before peeling off the carrier in the step 214, a glass substrate of the array substrate 170 can be replaced with a thin film material, so that the display module 100 has flexible features.

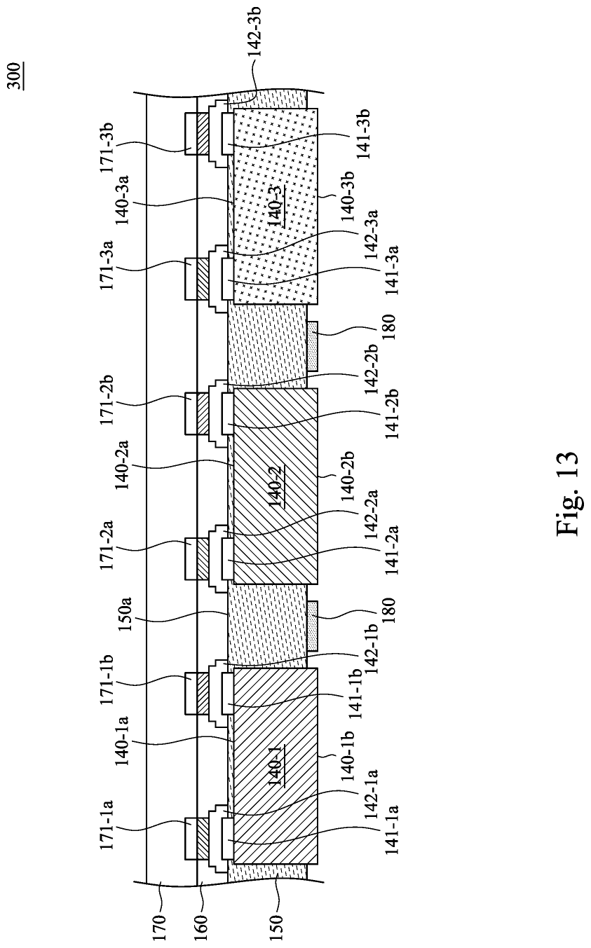

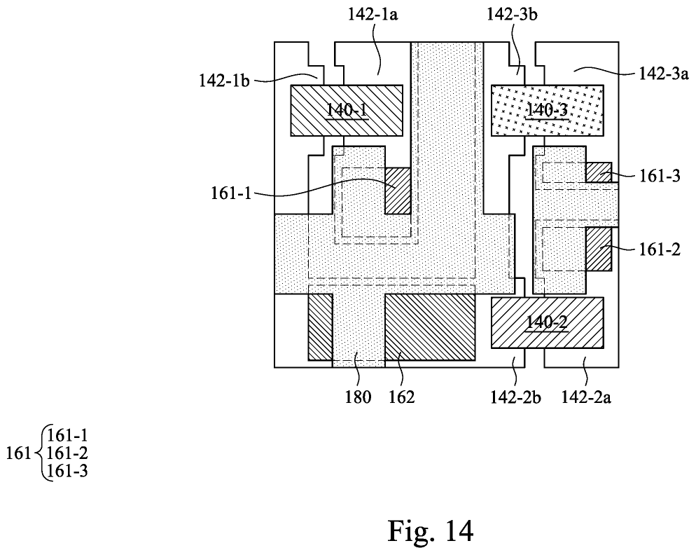

Reference is made to FIG. 13 and FIG. 14. FIG. 13 is a partial cross-sectional view of a display module 300 according to some embodiments of the present disclosure. FIG. 14 is a schematic diagram of the display module 300 according to some embodiments of the present disclosure. The difference between the display module 300 and the display module 100 is that, as shown in FIG. 13, the display module 300 further includes a plurality of touch sensing electrodes 180. The touch sensing electrodes 180 are disposed on the second surface 150b of the molding layer 150. The touch sensing electrodes 180 are configured to receive a first driving signal. Accordingly, the metal contact 142-1b, the metal contact 142-2b, and the metal contact 142-3b are configured to receive a second driving signal. The second driving signal is different from the first driving signal. In some embodiments, the first driving signal is a receiving signal (Rx), while the second driving signal is a transmitting signal (Tx). In some embodiments, the metal contact 142-1b, the metal contact 142-2b, and the metal contact 142-3b further extend to the first surface 150a of the molding layer 150 and are opposite to the touch sensing electrodes 180 across the molding layer 150. The metal contact 142-1b, the metal contact 142-2b, the metal contact 142-3b, and the touch sensing electrodes 180 form a part of a mutual capacitance touch circuit.

In an embodiment in which the light-emitting elements are arranged in an L shape, the touch sensing electrodes 180 can be arranged in accordance with the positions of the metal contacts and the light-emitting elements, as shown in FIG. 14. As aforementioned, some components such as the molding layer 150 are omitted from the schematic diagrams of the present disclosure such as FIG. 14 for clarity.

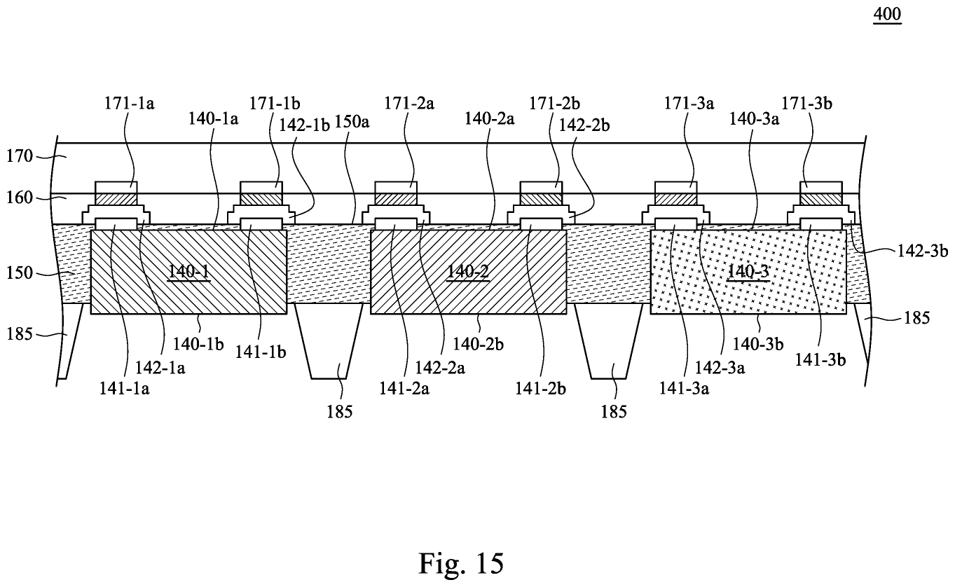

Reference is made to FIG. 15. FIG. 15 is a partial cross-sectional view of a display module 400 according to some embodiments of the present disclosure. The difference between the display module 400 and the display module 100 is that, as shown in FIG. 15, the display module 400 further includes micro structures 185. The micro structures 185 are disposed on the second surface 150b of the molding layer 150 and are disposed between the two light-emitting elements. For example, as shown in FIG. 15, the micro structures 185 are light-reflective micro structures disposed between any two light-emitting elements and configured to improve the luminous efficiency of the light-emitting elements.

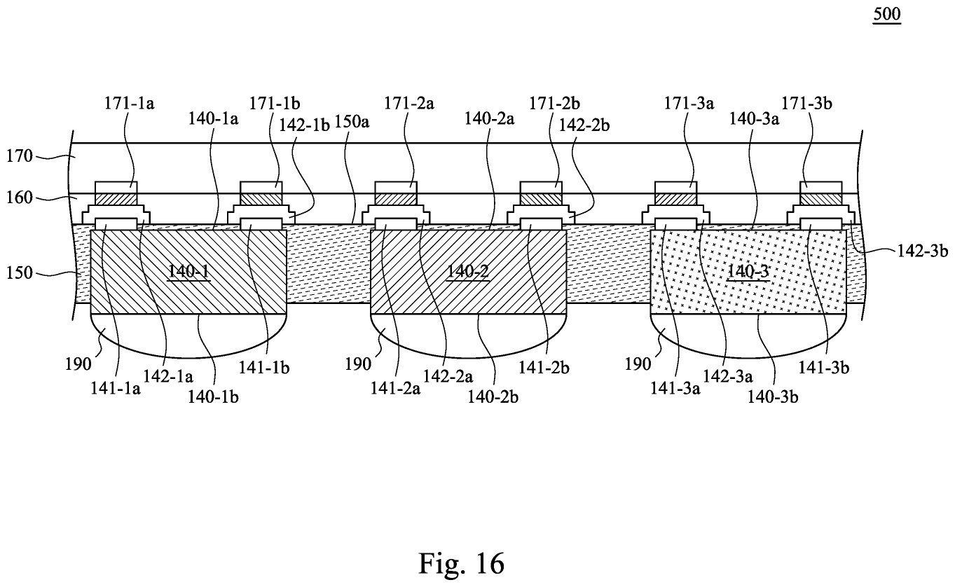

Reference is made to FIG. 16. FIG. 16 is a partial cross-sectional view of a display module 500 according to some embodiments of the present disclosure. The difference between the display module 500 and the display module 100 is that, as shown in FIG. 16, the display module 500 further includes micro lenses 190. The micro lenses 190 are disposed on the second surface of the light-emitting element, such as the second surface 140-1b of the light-emitting element 140-1. In some embodiments, a plurality of micro lenses 190 may be disposed on each of the second surfaces of the light-emitting elements as a micro lens array.

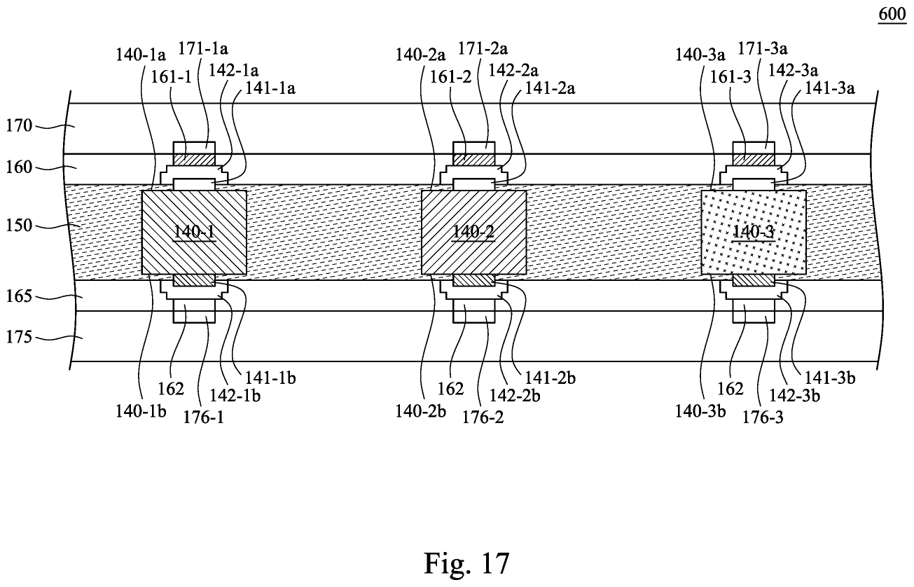

Reference is made to FIG. 17. FIG. 17 is a partial cross-sectional view of a display module 600 according to some embodiments of the present disclosure. The difference between the display module 600 and the display module 100 is that, as shown in FIG. 17, the light-emitting elements in the display module 600 are vertical light-emitting diodes. The display module 600 may further include an insulating layer 165 and a subtend substrate 175. One lead of each of the light-emitting elements is electrically connected to the array substrate 170 and the other lead is electrically connected to the subtend substrate 175. The insulating layer 165 includes a bonding layer 162. The subtend substrate 175 includes a third pad 176-1, a third pad 176-2, and a third pad 176-3.

Description will be given taking the light-emitting element 140-1 as a representative. As shown in FIG. 17, the first lead 141-1a of the light-emitting element 140-1 is disposed on the first surface 140-1a. The second lead 141-1b of the light-emitting element 140-1 is disposed on the second surface 140-1b. The first lead 141-1a is electrically connected to the first pad 171-1a of the array substrate 170 through the metal contact 142-1a and the bonding layer 161-1. The second lead 141-1b is electrically connected to the third pad 176-1 of the subtend substrate 175 through the metal contact 142-1b and the bonding layer 162.

In this embodiment, to remove the adhesive layer left when the second leads are peeled off from the carrier during the mass transfer, the molding layer 150 covers the second surfaces (light-emitting surfaces) of the light-emitting elements for protection during the etching process of removing the adhesive layer. For example, as shown in FIG. 17, the molding layer 150 covers the second surface 140-1b of the light-emitting element 140-1. The second lead 141-1b protrudes from the second surface 150b of the molding layer 150. The metal contact 142-1b covers the second lead 141-1b and extends from an upper surface of the second lead 141-1b through a side surface of the second lead 141-1b to the second surface 150b of the molding layer 150.

In some embodiments, as shown in FIG. 17, an insulating layer 165 is disposed between the molding layer 150 and the subtend substrate 175. Similar to the insulating layer 160 of the display module 100, the insulating layer 165 can conformally cover the metal contacts and the molding layer 150 or act as a planarization layer.

In some embodiments, to increase the light extraction efficiency of the light-emitting elements, a conductive layer such as an indium tin oxide (ITO) transparent conductive layer may be used to replace the bonding layer 162 and the subtend substrate 175. Such conductive layer is connected to the metal contacts of the light-emitting elements and is electrically connected to the second pad (not shown) of the array substrate 170 through wiring.

According to the foregoing recitations of the embodiments of the disclosure, it may be seen that in the display module and the method for forming the display module of some embodiments of the present disclosure, by disposing a molding layer laterally surrounding the light-emitting elements and covering part of the surfaces of the light-emitting elements, the light-emitting elements can be firmly positioned. At the same time, the molding layer can act as a protective layer during the manufacturing processes to prevent the adhesive layers used for positioning the light-emitting elements and/or the light-emitting surfaces of the light-emitting elements from being affected by the ion bombardment processes. Thus, the success rate of bonding the light-emitting elements may be ensured. To be more specific, after the first mass transfer, a molding layer is formed to laterally surround the light-emitting elements and cover part of the surfaces of the light-emitting elements to protect the adhesive layer that positions the light-emitting elements and/or the light-emitting surfaces of the light-emitting elements when the adhesive residues resulted from the first mass transfer is removed. The molding layer is affected by the ion bombardment processes and thus a surface of the molding layer that is adjacent to where the light-emitting elements are adhered is formed into a coarse surface. Compared with common display modules and methods for forming display modules, the positioning of the light-emitting elements can be strengthened, thereby improving the success rate of bonding and electrically connecting the light-emitting elements.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A display module, comprising:
a light-emitting element having a first surface and a second surface opposite to each other and further comprising a lead disposed on the first surface;
a molding layer laterally surrounding the light-emitting element and having a first surface and a second surface opposite to each other, wherein the first surface of the molding layer is adjacent to the first surface of the light-emitting element, and the first surface of the molding layer is a coarse surface;
a metal contact covering the lead of the light-emitting element;
an insulating layer covering the metal contact and the molding layer; and
an array substrate disposed on the insulating layer and having a pad configured to be electrically connected to the metal contact.

2. The display module of claim 1, wherein a roughness of the first surface of the molding layer is greater than a roughness of the second surface of the molding layer.

3. The display module of claim 1, wherein a roughness of the first surface of the molding layer is greater than a roughness of a surface of the metal contact.

4. The display module of claim 1, wherein a roughness of the first surface of the molding layer is greater than a roughness of the second surface of the light-emitting element.

5. The display module of claim 1, wherein the molding layer covers the first surface of the light-emitting element, and the lead of the light-emitting element passes through the molding layer and contacts the metal contact.

6. The display module of claim 5, wherein the lead of the light-emitting element protrudes from the first surface of the molding layer.

7. The display module of claim 6, wherein the metal contact extends from an upper surface of the lead, through a side surface of the lead, to the first surface of the molding layer.

8. The display module of claim 1, further comprising a touch sensing electrode disposed on the second surface of the molding layer, wherein the touch sensing electrode is configured to receive a first driving signal, the metal contact is configured to receive a second driving signal, and the second driving signal is different from the first driving signal.

9. A method for forming a display module, comprising:
providing a carrier with a light-emitting element, wherein the light-emitting element is disposed on the carrier through an adhesive layer, the light-emitting element has a plurality of leads disposed on a surface of the light-emitting element that is opposite to the carrier, the plurality of leads is covered by an adhesive residue, and the adhesive residue is separated from the surface of the light-emitting element;
forming a molding layer to cover the carrier and laterally surround the light-emitting element;
performing an etching process to remove the adhesive residue to expose the plurality of leads and to form a first surface of the molding layer into a coarse surface, wherein the first surface of the molding layer is opposite to the carrier;
forming a plurality of metal contacts covering the plurality of leads, wherein the plurality of metal contacts is separated from each other; and
disposing an array substrate electrically connected to the plurality of metal contacts.

10. The method for forming the display module of claim 9, further comprising:
peeling off the carrier; and
performing another etching process to remove the adhesive layer to expose a light-emitting surface of the light-emitting element and to form a second surface of the molding layer opposite to the first surface into a coarse surface, wherein a roughness of the second surface is smaller than a roughness of the first surface.

11. The method for forming the display module of claim 10, wherein a roughness of the light-emitting surface of the light-emitting element is smaller than a roughness of the first surface of the molding layer.

12. The method for forming the display module of claim 10, wherein after removing the adhesive layer, the light-emitting element protrudes from the second surface of the molding layer.

13. The method for forming the display module of claim 9, wherein a roughness of the first surface of the molding layer is greater than a roughness of a plurality of surfaces of the plurality of metal contacts.

14. The method for forming the display module of claim 9, wherein after removing the adhesive residue, the plurality of leads of the light-emitting element protrudes from the first surface of the molding layer.

15. The method for forming the display module of claim 9, wherein the adhesive layer is protected by the molding layer during the etching process.
